(19) United States
(12) Patent Application Publication
(10) Pub. No.: US 2017/0172004 A1
(43) Pub. Date: Jun. 15, 2017

(54) CARD TRAY FOR ELECTRONIC DEVICE

(71) Applicant: Molex, LLC, Lisle, IL (US)

(72) Inventors: In Chull YANG, Ansan (KR); Da Woon LEE, Ansan (KR)

(73) Assignee: Molex, LLC, Lisle, IL (US)

(21) Appl. No.: 15/340,412

(22) Filed: Nov. 1, 2016

(30) Foreign Application Priority Data
Dec. 11, 2015 (KR) 10-2015-0177200

(51) Int. Cl. H05K 5/02; H05K 5/04; H05K 7/14

(52) U.S. Cl. CPC H05K 5/0286; H05K 7/1427; H05K 5/04

(57) ABSTRACT

A card tray is provided for use in an electronic device that may prevent a card mounted in the tray from dropping out when the tray is withdrawn. The card tray for electronic devices according to an embodiment of this disclosure may be a card tray for use in an electronic device for insertion into and withdrawal from a card socket of an electronic device while a card is loaded thereon. The card tray includes a tray body and a card holding part. The tray body has a card mounting part formed thereon, the card mounting part being where a card is mounted. The card holding part is furnished on the tray body that holds the card in place so that a card that has been mounted on the card mounting part does not fall away from the tray body when the tray is withdrawn.

### RELATED APPLICATIONS

This application claims priority to Korean Application No. 10-2015-0177200, filed Dec. 11, 2015, which is incorporated herein by reference in its entirety.

### TECHNICAL FIELD

This disclosure relates to a card tray, and more specifically, to a card tray for use in an electronic device for inserting and withdrawing a tray on which a card is mounted.

### BACKGROUND ART

Generally, with regard to electronic devices such as smartphones in which various cards (memory cards or SIM cards) are mounted, for convenience of use the cards are loaded on a tray for insertion and extraction.

In the prior art, because the structure has been adopted in which the card is simply mounted on the tray body, the card is not firmly secured in place on the tray when withdrawn; in addition, if a card is loaded onto both sides of the tray, then because the card is not secured to the tray body, the card loaded onto the bottom face of the tray would tend to drop off.

In addition, there has been the problem that if the card tray is made of a plastic material, the durability of the tray is poor compared to card trays made from metal materials; in particular, because the tray body has weak bending strength in the length direction, the tray is subject to twisting and damage.

Patent Reference 1: ROK Registered Patent Gazette No. 10-1468952 (2014 Dec. 4)

### SUMMARY

The card tray of the present disclosure is for use in electronic devices that can prevent a card mounted in the tray from falling out when the tray is withdrawn.

The card tray of the present disclosure is further for electronic devices that enables prevention of tray twisting and damage by enhancing the tray's strength.

To achieve the above, the card tray for electronic devices according to an embodiment of this disclosure may be a card tray for use in an electronic device for insertion into and withdrawal from a card socket of an electronic device while a card is loaded thereon, comprising: a tray body whereon is formed a card mounting part whereon the card is mounted; and a card holding means furnished on the tray body that holds the card in place so that the card that has been mounted on the card mounting part does not fall away from the tray body when the tray is withdrawn.

In addition, the card holding means may comprise an elastic part that is installed on the side of the card mounting part of the tray body, and utilizes the elasticity of the card tray from the outside to the inside to hold in place the card mounted on the card mounting part.

In addition, the elastic part either may be furnished on the side of the tray body so as to be capable of horizontal movement in the width or length direction of the card, or maybe inserted into the elongated hole or aperture groove formed in the tray body, while a projecting part is formed that protrudes into the card mounting part; when the card is mounted in the card mounting part, it may held in place by the projecting part by an interference fit, while the elastic part may move in the width or length direction of the card so as to press elastically on the card.

In addition, the elastic part may be formed on a downwardly-sloping face on the inside of the projecting part, so that the side of the card is caused to be smoothly inserted and mounted by the sloping face of the projecting part.

In addition, the card holding means may comprise: a 1st card holding part that is furnished on one side of the tray body, and holds the side of the card mounted on one side of the tray body in place using elasticity.

In addition, in a card tray for insertion into and withdrawal from a card socket of an electronic device while a card is mounted on both sides, the card holding means may further comprise: a 2nd card holding part that consists of an elastic part insert-molded on the other side of the tray body, and holds the side of the card mounted on the other side of the tray body in place using elasticity.

In addition, the 2nd card holding means may be furnished on both the top and bottom sides of the other side of the tray body, so as to hold the card in place by applying elastic pressure to the top and bottom of the side of the card mounted on the other side of the tray body.

In addition, the card tray may further comprise a metal frame part that is insert-molded onto the tray body.

In addition, the metal frame part may have a bending part formed on its edge, so as to reinforce the bending strength of the tray body.

In addition, the elastic part may move horizontally on the top face of the metal frame part, in a length or width direction of the card.

In addition, the range of horizontal motion of the elastic part may be configured so as to be less than or equal to the width of the top exposed part of the metal frame part.

The card tray for electronic devices of this disclosure, and the tray carrier assembly using the same, have the following effects.

First, this disclosure can prevent a card mounted in the tray from dropping out when the tray is withdrawn, because a card holding means is furnished that is insert-molded to either side of the card mounting part of the tray body so as to hold either side of the card that is mounted in the card mounting part in place using elasticity.

Second, this disclosure can reliably prevent cards mounted on the top and bottom faces of a tray from dropping off, because when a card is loaded onto both sides of the tray in this disclosure, both ends of the cards are held in place by an interference fit by the projecting part of the elastic part that is insert-molded onto either side of the tray, and in that case, the elastic part elastically presses on the cards that are mounted on the top and bottom faces of the tray.

Third, this disclosure can effectively hold the card in place without being thick in the thickness direction of the card.

Fourth, by configuring the card tray by insert-molding a metal frame part of a metal material onto a tray body of plastic material, this disclosure can reduce the size and increase the durability of trays relative to existing card trays made of plastic alone.

Fifth, this disclosure can prevent twisting and damage to the tray by forming a bending part on the edge of the metal frame part that is insert-molded onto the card tray, so as to reinforce the bending strength of the card tray in the length direction.

### BRIEF DESCRIPTION OF THE DRAWINGS

FIG. 1 is a perspective view of the card tray for use in an electronic device according to one embodiment of this disclosure, viewed from above.

FIG. 2 is a perspective view of the card tray for use in an electronic device according to one embodiment of this disclosure, viewed from above.

FIG. 3 is a perspective view of the metal frame part insert-molded onto the card tray of this disclosure for use in an electronic device.

FIG. 4 is a top view of the top part of the card tray of this disclosure for use in an electronic device.

FIG. 5 is an enlarged partial view of portion A in FIG. 4.

FIG. 6 is a top view of the card tray of this disclosure for use in an electronic device.

FIG. 7 is an enlarged partial view of portion B in FIG. 6.

FIG. 8 is a cross-section along the X-X line of FIG. 6.

FIGS. 9A and 9B show the state in which a card is mounted and held in place in the card tray of this disclosure for use in an electronic device.

FIG. 10 is a reference diagram illustrating the reinforcement of the bending strength of the card tray by the metal frame part that is used in the card tray of this disclosure for use in an electronic device.

### DETAILED DESCRIPTION OF THE PREFERRED EMBODIMENTS

Hereinbelow, a preferred embodiment of the card tray of this disclosure for use in an electronic device will be described, with reference to the attached drawings. Please note that in describing this disclosure, the detailed explanation is omitted of functions and components which are common knowledge and are judged to unnecessarily obscure the core intent of the disclosure.

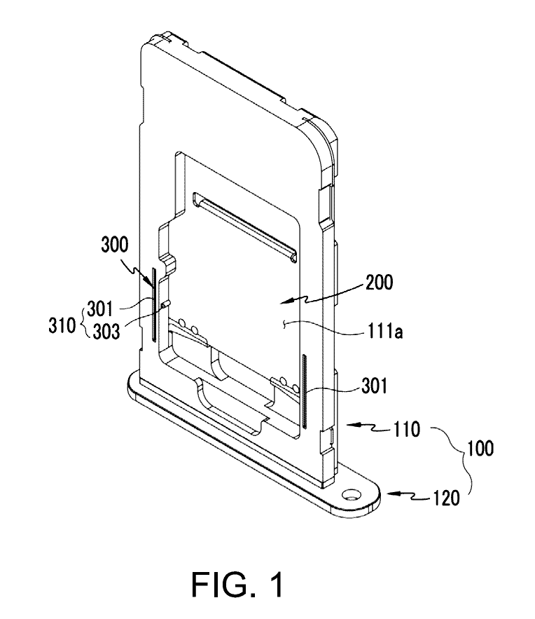

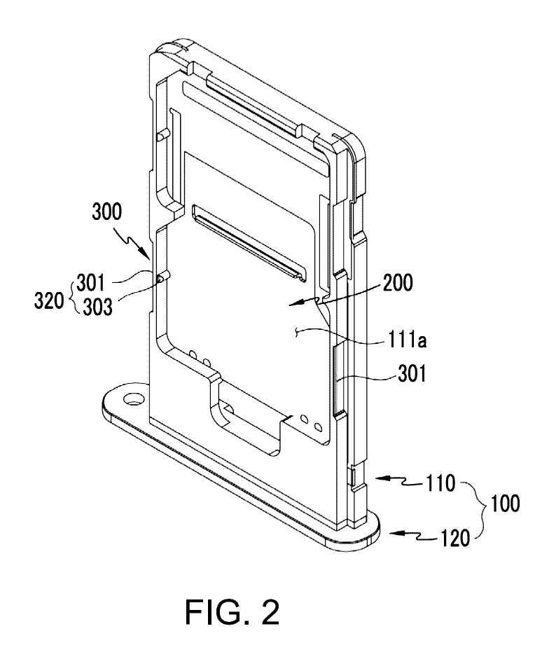

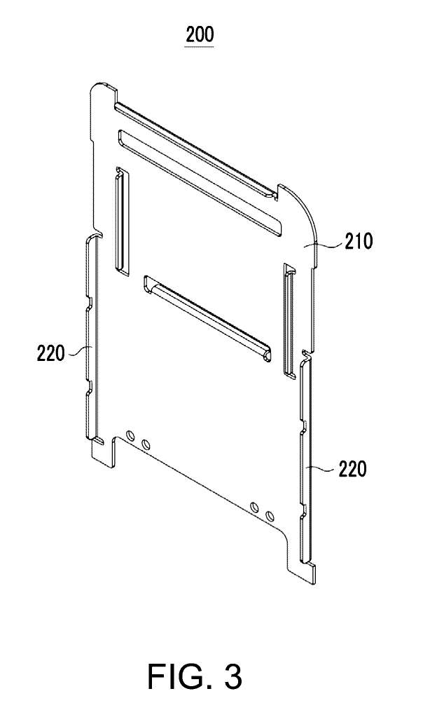

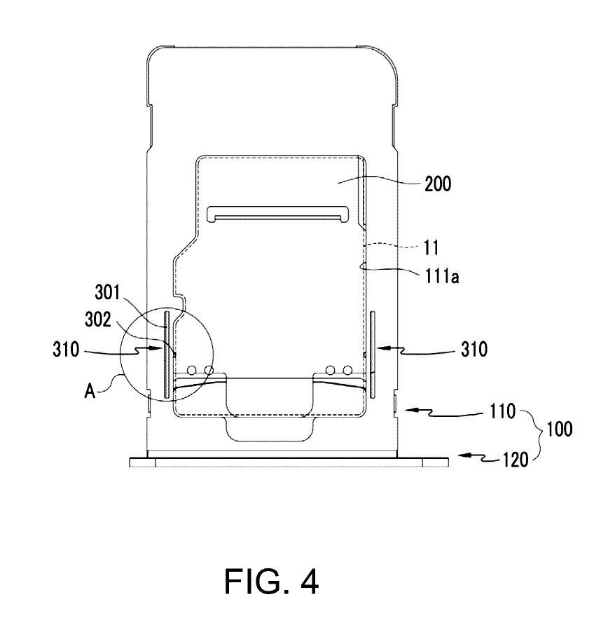

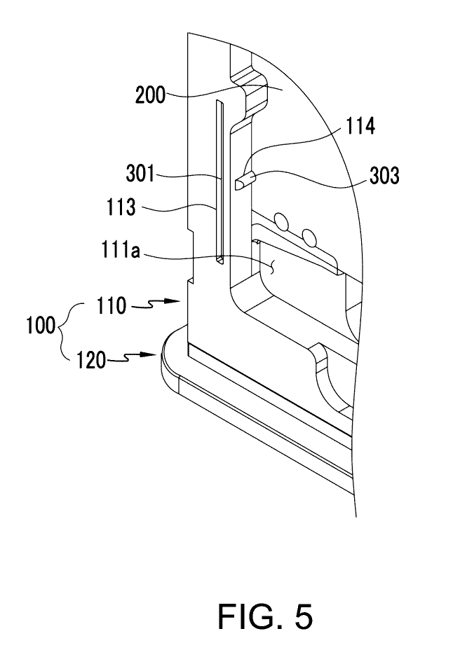

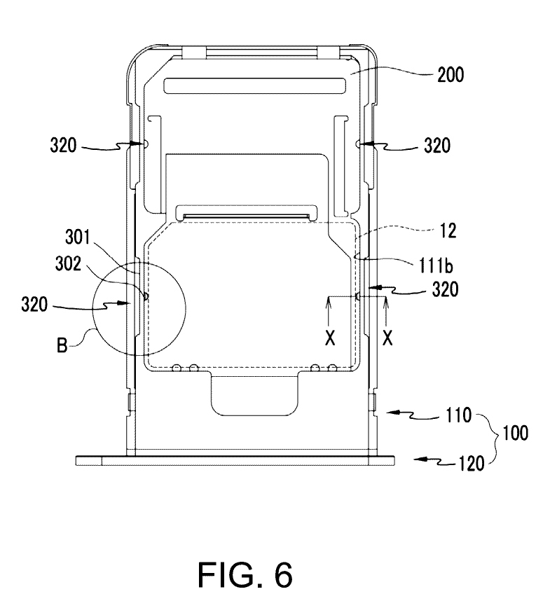

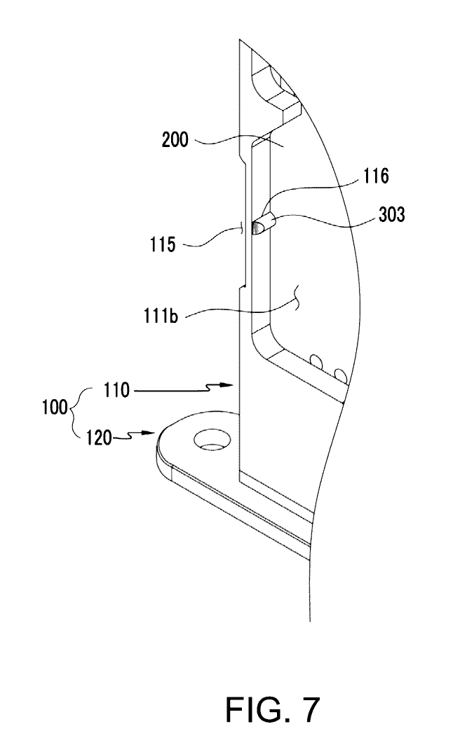

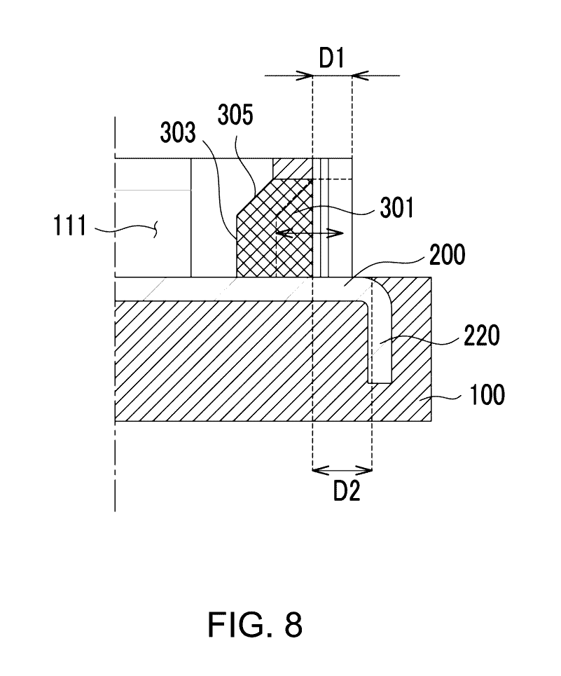

As shown in FIGS. 1 through 8, the card tray for use in an electronic device according to an embodiment of this disclosure may comprise a tray body 100, metal frame part 200, and card holding means 300.

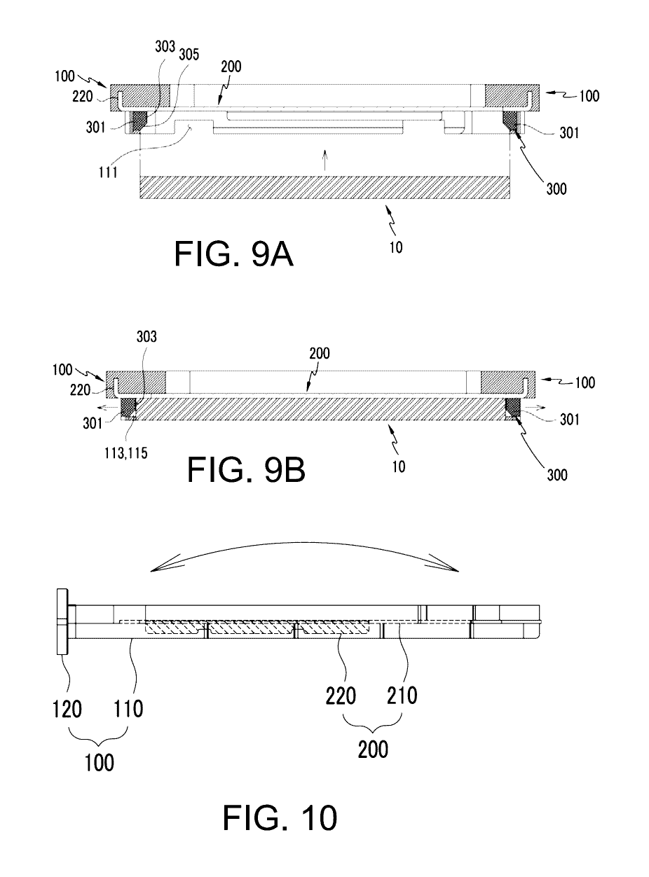

Although this embodiment illustrates the case of a card tray loaded with cards (10, see FIGS. 9A and 9B) on both sides, i.e. both top and bottom, the disclosure is not limited thereto, and may be applied to a card tray in which a card 10 is loaded onto only one of the top or bottom faces.

The tray body 100 comprises: a card mounting part 110 having an overall rectilinear shape, with a card mounting part 111 formed in the center whereinto the card 10 is inserted and mounted; and a handle part 120 formed on the card mounting part 110 so that when inserting/withdrawing the card tray from the card socket (not shown), it can be gripped by hand and either pushed or pulled. When the tray body 100 is inserted into the card socket, the card mounting part 110 is inserted into the tray insertion path while the handle part 120 is positioned at the entrance to the tray insertion path.

In addition, the tray body 100, when mounted in the card socket, may have a structure such that it does not make electrical contact with the various terminals of the card socket, or may be made of a nonconductor, for example a nonmetallic material such as plastic.

The metal frame part 200 is inserted-molded to the tray body 100 so as to reinforce the tray. This metal frame part 200 consists of a metal sheet having a rectilinear shape corresponding to the shape of the tray body 100. Accordingly, the strength of the card tray of this disclosure may be increased and the size may be reduced beyond that of existing card trays made only from plastic materials, because the metal frame part 200 made of a metal material is insert-molded onto the tray body 100 made of a plastic material.

The metal frame part 200 is insert-molded to the tray body 100 so as to block off and partition the upper aperture area 111a of the card mounting part 111 from the lower aperture area 111b. By this means, relative to the metal frame part 200, a 1st card 11 may be inserted and mounted on the upper aperture area 111a of the card mounting part 111, and a 2nd card 12 may be inserted and mounted on the lower aperture area 111b of the card mounting part 111, so that a card is loaded onto either side of the tray.

The metal frame part 200 may improve the bending strength of the tray body 100 because a bending part 220 is formed on the end of the metal sheet 210, especially at either end corresponding to the width or length direction of the card 10. Although this embodiment has illustrated a configuration in which the bending part 220 is formed only on part of each end of the metal frame part 200, the disclosure is not limited thereto, and a bending part 220 may also be formed on the entire end of the metal frame part 200.

The card holding means 300 is furnished on the tray body 100 and serves to hold the card 10 in place so that a card 10 that is mounted in the card mounting part 111 does not fall out of the tray body 100 when the tray is withdrawn.

The card holding means 300 may comprise an elastic part 301 that is insert-molded onto either side of the card mounting part 111 of the tray body 100 so as to hold in place both ends of the card 10 mounted on the card mounting part 111, using elasticity. The elastic part 301 may be made of either a metal or a plastic material having elasticity.

The elastic part 301 may be furnished on the side of the tray body so as to be capable of horizontal movement in the width or length direction of the card 10, or may be inserted into the elongated hole 113 or aperture groove 115 formed on either side of the tray body 100, while a projecting part 303 is formed that protrudes into the card mounting part 111; and when the card 10 is mounted in the card mounting part 111, it may be interference-fit by the projecting part, while the elastic part 301 presses elastically on the card 10 by moving in the width or length direction of the card within the elongated hole 113 or aperture groove 115.

The elastic part 301 may move horizontally in the width or length direction of the card 10 on the top face of the metal frame part 200 that is insert-molded onto the tray body 100. In that case, the range of horizontal motion D1 of the elastic part 301 is preferably less than or equal to the width D2 of the top exposed part of the metal frame part 200.

The elastic part 301 is formed on a downwardly-sloping face 305 on the inside of the projecting part 303, so that the sloping face 305 of the projecting part 303 causes both sides of the card 10 to be smoothly inserted and mounted in the card mounting part 111.

The card holding means 300 may comprise a 1st card holding part 310 and a 2nd card holding part 320.

The 1st card holding part 310 consists of an elastic part 301 that is insert-molded to either side of one face, e.g. the top face, of the tray body 100; because it holds in place both sides of the card 10 mounted onto the top of the tray body 100 using elasticity, when the tray is withdrawn, the 1st card 11 mounted on the top face of the tray may be prevented from falling out. The elastic part 301 of the 1st card holding part 310 is formed in a rod shape, and is inserted into the elongated hole 113 formed on either side of the top face of the tray body 100, so as to enable horizontal motion of the card 10 from the outside to the inside. In the elastic part 301 of the 1st card holding part 310, a projecting part 303 is formed and the projecting part 303 protrudes into the card mounting part 111 via the hole 114 formed on the side of the top face of the tray body 100. When the card 10 is mounted on the card mounting part 111 on the top face of the tray body 100, either end of the card 10 is interference-fit by the projecting part 303, and as the elastic part 301 then moves horizontally within the elongated hole 113, the card 10 that is mounted on the top face of the tray is held in place by elastic pressure so that the card 10 does not fall out.

The 2nd card holding part 320 consists of an elastic part 301 that is insert-molded to either side of the opposite face of the tray body 100, e.g. the bottom face; by holding either side of the card 10 mounted onto the top of the tray body 100 using elasticity, when the tray is withdrawn, the 2nd card 12 mounted on the top face of the tray may be prevented from falling out. The elastic part 301 of the 2nd card holding part 320 is formed in a rod shape, and is inserted into the aperture groove 115 formed on either side of the bottom face of the tray body 100, so as to enable horizontal motion of the card 10 from the outside to the inside. In the elastic part 301 of the 2nd card holding part 320, a projecting part 303 is formed and the projecting part 303 protrudes into the card mounting part 111 via the hole 116 formed on the side of the bottom face of the tray body 100. When the card 10 is mounted on the card mounting part 111 on the bottom face of the tray body 100, either end of the card 10 is interference-fit by the projecting part 303, and as the elastic part 301 then moves horizontally within the aperture groove 115, the card 10 that is mounted on the bottom face of the tray is held in place by elastic pressure so that the card 10 does not fall out.

In addition, the elastic part 303 of the 2nd card holding part 320 is furnished on the top and bottom of either side of the bottom face of the tray body 100, so that it may more securely hold in place the 2nd card 12, mounted on the bottom face of the tray body 100, by elastic pressure on the top and bottom respectively.

FIGS. 9A and 9B show by way of example the case in which the card 10 is loaded onto the bottom face of the tray; because this is identical to the case in which the card 10 is loaded onto the bottom face or both faces of the tray, the detailed explanation thereof is omitted.

As shown in FIG. 9A, in order to load the card 10 onto the top face or bottom face, or both faces, the card 10 is inserted into and mounted on the card mounting part 111 of the tray body 100. Before the card 10 is mounted in the tray, the projecting part 303 of the elastic part 301 insert-molded onto either side of the tray body 100 protrudes into the card mounting part 111.

As shown in FIG. 9B, when the card 10 is inserted into and mounted on the card mounting part 111, either end of the card 10 pushes the projecting part 303 of the elastic part 301 outward from the card mounting part 111 while it is interference-fit by the projecting part 303, and as the elastic part 301 then moves horizontally within the elongated hole 113 or aperture groove 115, the card 10 that is mounted on the top or bottom face of the tray body 100 is held in place by elastic pressure so that the card 10 does not fall out.

As shown in FIG. 10, the tray strength may be increased, because the metal frame part 200 of a metal material is insert-molded onto the tray body 100 of a plastic material. Specifically, the metal frame part 200 may improve the bending strength (in the arrow direction) in the width direction of the card mounting part 110 of the tray body 100 because a bending part 220 is formed on the end of the metal sheet 210, at either end along the width or length direction of the card.

Hereinabove, embodiments of this disclosure were described with reference to the attached drawings, but a person of ordinary skill in the art to which this disclosure pertains will be able to understand that this disclosure can be implemented in different specific forms without altering the necessary characteristics or technical idea thereof. Therefore, the embodiments described hereinabove must be understood as exemplary, rather than limiting, in all respects. The scope of this disclosure is set forth in the claims below rather than in the detailed description; all alterations or altered forms derived from the meaning, scope and equivalents of the claims must be considered to be included within the scope of this disclosure.

1. A card tray for use in an electronic device for insertion into and withdrawal from a card socket of an electronic device while a card is loaded thereon, the card tray comprising:
a tray body whereon is formed a card mounting part whereon the card is mounted; and
a card holding part furnished on the tray body that holds the card in place so that the card that has been mounted on the card mounting part does not fall away from the tray body when the tray is withdrawn.

2. The card according to claim 1, wherein the card holding part comprises an elastic part that is installed on the side of the card mounting part of the tray body, and utilizes the elasticity of the card tray from the outside to the inside to hold in place the card mounted on the card mounting part.

3. The card tray according to claim 2, wherein the elastic part is either furnished on the side of the tray body so as to be capable of horizontal movement in the width or length direction of the card, or is inserted into the elongated hole or aperture groove formed on the tray body, while a projecting part is formed that protrudes into the card mounting part; and wherein when the card is mounted in the card mounting part, it is interference-fit by the projecting part, while the elastic part presses elastically on the card by moving in the width or length direction of the card.

4. The card tray according to claim 3, wherein the elastic part is formed on a downwardly-sloping face on the inside of the projecting part, so that the side of the card is caused to be smoothly inserted and mounted by the sloping face of the projecting part.

5. The card tray according to claim 2, wherein the card tray further comprises a metal frame part that is insert-molded onto the tray body.

6. The card tray according to claim 5, wherein the metal frame part has a bending part formed on its edge, so as to reinforce the bending strength of the tray body.

7. The card tray according to claim 5, wherein the elastic part moves horizontally on the top face of the metal frame part, in a length or width direction of the card.

8. The card tray according to claim 8, wherein the range of horizontal motion of the elastic part is less than or equal to the width of the top exposed part of the metal frame part.

9. The card tray according to claim 1, wherein the card holding part comprises: a 1st card holding part that is furnished on one side of the tray body, and holds the side of the card mounted on one side of the tray body in place using elasticity.

10. The card tray according to claim 9, for insertion into and withdrawal from a card socket of an electronic device while a card is mounted on both sides, and wherein the card holding means further comprises: a 2nd card holding part that consists of an elastic part insert-molded on the other side of the tray body, and holds the side of the card mounted on the other side of the tray body in place using elasticity.

11. The card tray according to claim 10, wherein the 2nd card holding part is furnished on both the top and bottom sides of the other side of the tray body, so as to hold the card in place by applying elastic pressure to the top and bottom of the side of the card mounted on the other side of the tray body.
